(19) United States
(12) Patent Application Publication
(10) Pub. No.: US 2025/0392286 A1
(43) Pub. Date: Dec. 25, 2025

(54) SYSTEM APPROACH FOR BAW TEMPCO REDUCTION

(71) Applicant: Qorvo US, Inc., Greensboro, NC (US)

(72) Inventor: Chris Levesque, Fountain Valley, CA (US)

(21) Appl. No.: 19/215,466

(22) Filed: May 22, 2025

Related U.S. Application Data
(60) Provisional application No. 63/661,956, filed on Jun. 20, 2024.

(51) Int. Cl. H03H 9/54; H03H 9/56; H03H 11/04

(52) U.S. Cl. CPC H03H 9/545; H03H 9/568; H03H 11/04

(57) ABSTRACT

A radio frequency (RF) circuit and methods of operating the same are disclosed. The RF circuit includes an acoustic filter, upstream/downstream circuitry, a switch device, and temperature circuitry. The acoustic filter includes a first filter path that includes a first acoustic resonator and a second filter path that includes a second acoustic resonator. The switch device is configured to selectively couple the upstream/downstream circuitry to the first filter path and to the second filter path. The temperature circuitry is configured to measure a measured temperature that is related to a filter temperature of the acoustic filter. To compensate for temperature drift in the acoustic filter, the temperature circuitry is configured to operate the switch device such that the first filter path or the second filter path is selectively coupled depending on the measured temperature.

### RELATED APPLICATIONS

This application claims the benefit of provisional patent application Ser. No. 63/661,956, filed Jun. 20, 2024, the disclosure of which is hereby incorporated herein by reference in its entirety.

### FIELD OF THE DISCLOSURE

This disclosure relates generally to radio frequency (RF) circuits that utilize acoustic filters to provide a passband.

### BACKGROUND

Acoustic filters are utilized in front-end radio frequency (RF) modules in order to isolate desired signals while rejecting unwanted interference, noise, and adjacent channel signals. Utilizing the piezoelectric effect, acoustic filters can precisely manipulate acoustic waves to achieve high selectivity and low insertion losses, thereby maximizing key metrics for optimizing signal quality. Whether it's in cellular networks, Wi-Fi, or Bluetooth connections, acoustic filters help ensure reliable and efficient communication by maintaining signal integrity and minimizing interference, ultimately enhancing the overall performance of RF modules in modern wireless devices.

Unfortunately, acoustic filters also suffer from temperature drift. As the temperature of the acoustic filter increases, a passband provided by the acoustic filter moves down in frequency. Additionally, as the temperature of the acoustic filter decreases, the passband provided by the acoustic filter moves up in frequency. The temperature drift of the acoustic filter can increase insertion losses and lead to other performance losses in the operation of the RF module.

### SUMMARY

In some embodiments, a radio frequency (RF) circuit includes: an acoustic filter including a first filter path that includes a first acoustic resonator and a second filter path that includes a second acoustic resonator; upstream/downstream RF circuitry; a switch device configured to selectively couple the upstream/downstream RF circuitry to the first filter path and to the second filter path; and temperature circuitry configured to measure a measured temperature that is related to a filter temperature of the acoustic filter, the temperature circuitry is configured to operate the switch device such that the first filter path is selectively coupled in response to the measured temperature being below a threshold temperature value and such that the second filter path is selected in response to the measured temperature being above the threshold temperature value. In some embodiments, the threshold temperature value is a first threshold temperature; the acoustic filter further includes a third filter path that includes a third acoustic filter; the switch device is further configured to selectively couple the upstream/downstream RF circuitry to the third filter path; and the temperature circuitry is configured to operate the switch device so as to selectively couple the upstream/downstream RF circuitry to the second filter path in response to the measured temperature being below a second threshold temperature and so as to selectively couple the upstream/downstream RF circuitry to the third filter path in response to the measured temperature being above the second threshold temperature, wherein the second threshold temperature is higher than the first threshold temperature. In some embodiments, the acoustic filter defines a passband and wherein the passband is shifted to higher frequencies in response to the first filter path being selectively coupled to the upstream/downstream RF circuitry and the passband is shifted to lower frequencies in response to the second filter path being selectively coupled to the upstream/downstream RF circuitry. In some embodiments, the acoustic filter includes a plurality of acoustic resonators including the first acoustic resonator and the second acoustic resonator; the first filter path is a first input filter path of the acoustic filter; and the second filter path is a second input filter path of the acoustic filter, wherein the first input filter path and the second input filter path are connected in parallel such that the upstream/downstream RF circuitry is selectively coupled by the switch device to the acoustic filter through the first input filter path or through the second input filter path. In some embodiments, the acoustic filter is a bulk acoustic wave (BAW) filter. In some embodiments, the first acoustic resonator is a first BAW resonator and the second acoustic resonator is a second BAW resonator. In some embodiments, the acoustic filter includes a plurality of acoustic resonators including the first acoustic resonator and the second acoustic resonator; the first filter path is a first shunt filter path of the acoustic filter; and the second filter path is a second shunt filter path of the acoustic filter, wherein the first shunt filter path and the second shunt filter path are selectively coupled in shunt to an RF signal line in the acoustic filter by the switch device. In some embodiments, the acoustic filter is a BAW filter. In some embodiments, the first acoustic resonator is a first BAW resonator and the second acoustic resonator is a second BAW resonator. In some embodiments, the upstream/downstream RF circuitry includes a power amplifier (PA). In some embodiments, the upstream/downstream RF circuitry includes a low noise amplifier (LNA).

In some embodiments, a method of operating an RF circuit includes: measuring a measured temperature that is related to a filter temperature of an acoustic filter; operating a switch device such that a first filter path in the acoustic filter is selectively coupled to upstream/downstream circuitry in response to the measured temperature being below a threshold temperature value; and operating the switch device such that a second filter path in the acoustic filter is selectively coupled to the upstream/downstream circuitry in response to the measured temperature being above the threshold temperature value.

In some embodiments, a user element includes an RF circuit, the RF circuit including: an acoustic filter that includes a first filter path that includes a first acoustic resonator and a second filter path that includes a second acoustic resonator; upstream/downstream RF circuitry; a switch device configured to selectively couple the upstream/downstream RF circuitry to the first filter path and to the second filter path; and temperature circuitry configured to measure a measured temperature that is related to a filter temperature of the acoustic filter, the temperature circuitry is configured to operate the switch device such that the first filter path is selectively coupled in response to the measured temperature being below a threshold temperature value and such that the second filter path is selected in response to the measured temperature being above the threshold temperature value. In some embodiments, the threshold temperature value is a first threshold temperature; the acoustic filter further includes a third filter path that includes a third acoustic filter; the switch device is further configured to selectively couple the upstream/downstream RF circuitry to the third filter path; and the temperature circuitry is configured to operate the switch device so as to selectively couple the upstream/downstream RF circuitry to the second filter path in response to the measured temperature being below a second threshold temperature and so as to selectively couple the upstream/downstream RF circuitry to the third filter path in response to the measured temperature being above the second threshold temperature, wherein the second threshold temperature is higher than the first threshold temperature. In some embodiments, the acoustic filter defines a passband wherein the passband is shifted to higher frequencies in response to the first filter path being selectively coupled to the upstream/downstream RF circuitry and the passband is shifted to lower frequencies in response to the second filter path being selectively coupled to the upstream/downstream RF circuitry. In some embodiments, the acoustic filter includes a plurality of acoustic resonators including the first acoustic resonator and the second acoustic resonator; the first filter path is a first input filter path of the acoustic filter; and the second filter path is a second input filter path of the acoustic filter, wherein the first input filter path and the second input filter path are connected in parallel such that the upstream/downstream RF circuitry is selectively coupled by the switch device to the acoustic filter through the first input filter path or through the second input filter path. In some embodiments, the acoustic filter includes a plurality of acoustic resonators including the first acoustic resonator and the second acoustic resonator; the first filter path is a first shunt filter path of the acoustic filter; and the second filter path is a second shunt filter path of the acoustic filter, wherein the first shunt filter path and the second shunt filter path are selectively coupled in shunt to an RF signal line in the acoustic filter by the switch device. In some embodiments, the acoustic filter is a BAW filter. In some embodiments, the upstream/downstream RF circuitry includes a PA. In some embodiments, the upstream/downstream RF circuitry includes an LNA.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a radio frequency (RF) circuit, in accordance with some embodiments;

FIG. 2 illustrates an upper band edge of a passband at different temperatures, in accordance with some embodiments;

FIG. 3 illustrates a lower band edge of a passband at different temperatures, in accordance with some embodiments;

FIG. 4 is a graph that illustrates frequency shift versus measured temperature related to a filter temperature of an acoustic filter shown in FIG. 1, in accordance with some embodiments;

FIG. 5 illustrates an RF circuit, in accordance with some embodiments;

FIG. 6A illustrates switch operation circuitry, in accordance with some embodiments;

FIG. 6B is a graph that illustrates logical states of switch operation circuitry versus a temperature sensor output, in accordance with some embodiments;

FIG. 7 is a flow diagram of a method of operating an RF circuit, in accordance with some embodiments; and

FIG. 8 is a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying embodiments.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Embodiments of radio frequency (RF) circuits and methods of operating the same are disclosed. The RF circuits include upstream/downstream circuitry and an acoustic filter used to filter transmit RF signals and/or receive RF signals. Frequencies of a passband provided by the acoustic filter have a negative relationship with respect to temperature of the acoustic filter. Accordingly, as the temperature of the acoustic filter rises, the passband moves down with respect to frequency. Additionally, as the temperature of the acoustic filter decreases, the passband moves up with respect to frequency. The RF circuits include a switch device that is configured to selectively couple the upstream/downstream circuitry to different acoustic resonators in the acoustic filter. In this manner, as the temperature of the acoustic filter rises, the switch device is operated to selectively couple the upstream/downstream circuitry to a filter path with an acoustic resonator that moves the passband up in frequency. This compensates for the downward shift in frequency of the acoustic filter as the temperature rises. Furthermore, as the temperature of the acoustic filter decreases, the switch device is operated to selectively couple the upstream/downstream circuitry to a filter path with an acoustic resonator that moves the passband down in frequency. This compensates for the upward shift in frequency of the acoustic filter as the temperature decreases.

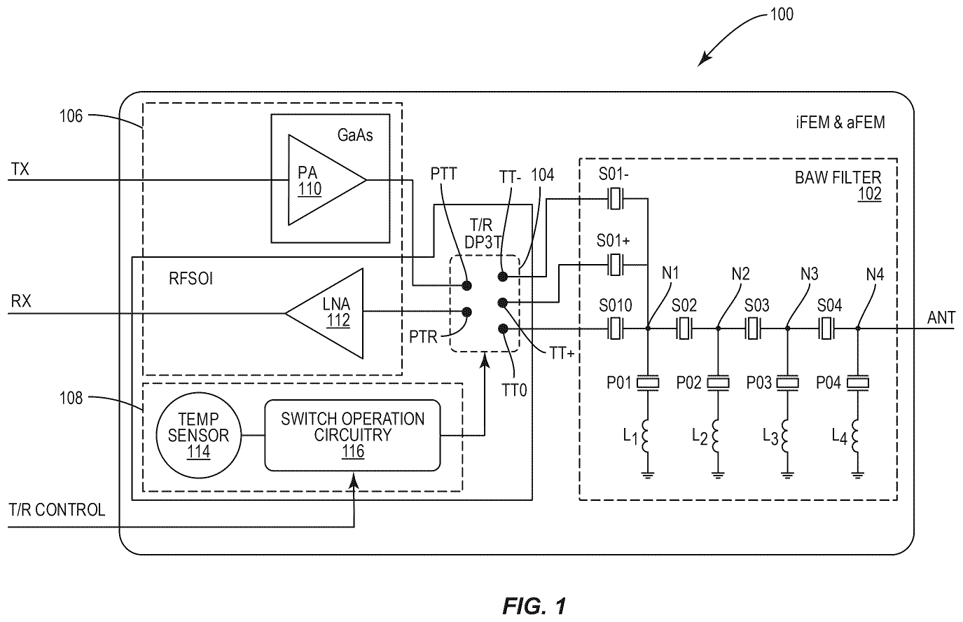

FIG. 1 illustrates an RF circuit 100, in accordance with some embodiments.

In some embodiments, the RF circuit 100 shown in FIG. 1 is a Wi-Fi Front-End-Module (FEM) that is provided in an integrated circuit (IC) package. Note that the arrangement of the RF circuit 100 is only one arrangement and that other embodiments of the RF circuit 100 may have other arrangements. The RF circuit 100 includes an acoustic filter 102, a switch device 104, upstream/downstream circuitry 106, and temperature circuitry 108. In FIG. 1, the acoustic filter 102 is a bulk acoustic wave (BAW) filter. In other embodiments, the acoustic filter 102 may be a surface acoustic wave (SAW) filter.

The acoustic filter 102 operates as an RF filter for the upstream/downstream circuitry 106. The upstream/downstream circuitry 106 may be either upstream circuitry that is upstream to the acoustic filter 102, downstream circuitry that is downstream from the acoustic filter 102, or both upstream and downstream circuitry that is upstream and downstream from the acoustic filter 102. As RF circuits (such as the RF circuit 100) increase integration levels of various components, FEMs are referenced with an “i” that stands for “integrated” or with an “a” that stands for “advanced.” IC packages that are iFEM and aFEM contain the required filtering and amplification that previously was provided in separate IC packages. In FIG. 1, the upstream/downstream circuitry 106 includes a power amplifier 110 that is upstream to the acoustic filter 102 and a low noise amplifier 112 that is downstream to the acoustic filter 102. Thus, in FIG. 1, the entire RF circuit 100 is included in a single IC package. Note that, while the RF circuit 100 is shown in a single IC package, other embodiments of the RF circuit 100 may be provided in multiple IC packages as different components of the RF circuit 100 may be included in different IC packages.

In FIG. 1, the power amplifier 110 is formed in a Gallium Arsenide (GaAs) die that is mounted in the IC package that provides the RF circuit 100. The power amplifier 110 has an input that is connected to a terminal Tx of the IC package. The terminal Tx is configured to receive an RF transmit signal from external upstream circuitry (not explicitly shown). In some embodiments, the RF transmit signal is on Wi-Fi frequency bands, which are 5.150 to 5.835 GHz, 5.945 to 7.125 GHz, and 2.4 to 2.83 GHz. However, these Wi-Fi frequency bands are non-limiting as the concepts disclosed herein are applicable to any frequency range related to acoustic technologies, which can be as low as 600 MHz and up to 18 GHz. An output of the power amplifier 110 is configured to output an amplified RF transmit signal. As explained in further detail below, the amplified RF transmit signal is then provided through the switch device 104, filtered by the acoustic filter 102, and then transmitted through an antenna terminal ANT, which may be connected externally to an antenna (not explicitly shown).

An RF receive signal may be received from an external antenna at the antenna terminal ANT. As explained in further detail below, the acoustic filter 102 is configured to filter the RF receive signal, which is then passed through the switch device 104. In some embodiments, the frequency ranges are the same frequency ranges mentioned above for the RF transmit signal. In some embodiments, the systems are Time Division Duplex (TDD) and/or Frequency Division Duplex (FDD) filters. The TDD and/or FDD filters will also be located within the same frequency range. In TDD systems, the transmit and receive frequencies are the same. In FDD system, the transmit and receive frequencies are different. The drawings in this application represent TDD systems. This is due to the fact that FDD systems only have two filters, one in the transmit path and a second one in the receive path. However, both systems would suffer the same due to temperature changes, which result in passband shifts in frequency. In FIG. 1, the RF receive signal is then provided to an input of the low noise amplifier 112, which is configured to amplify the RF receive signal. The amplified RF receive signal is transmitted from an output of the low noise amplifier 112 to a terminal Rx, where the amplified RF receive signal is transmitted to external circuitry (not explicitly shown).

Accordingly, in FIG. 1, the switch device 104 is configured to operate as a transmit and receive (T/R) switch so that the acoustic filter 102 is selectively coupled to either the power amplifier 110 or the low noise amplifier 112. Additionally, the acoustic filter 102 is configured to define a passband that drifts based on a filter temperature of the acoustic filter 102. More specifically, the acoustic filter 102 has a negative temperature coefficient with respect to frequency. This means that, as the temperature of the acoustic filter 102 increases, the passband of the acoustic filter 102 shifts down in frequency and, opposingly, as the temperature of the acoustic filter 102 decreases, the passband of the acoustic filter 102 shifts up in frequency. The temperature circuitry 108 is configured to measure a measured temperature that is related to the temperature of the acoustic filter 102 and operate the switch device 104 such that different components of the acoustic filter 102 are selectively coupled to the upstream/downstream circuitry 106. As explained in further detail below, as different components of the acoustic filter 102 are selectively coupled to the upstream/downstream circuitry 106, the drift in the passband of the acoustic filter 102 is reduced.

Reducing the frequency drift due to the temperature of the acoustic filter 102 is advantageous. For example, reducing the temperature drift of the acoustic filter 102 lowers insertion losses (ILs) because the passband of the acoustic filter 102 can be widened. Furthermore, ILs at the edges of the passband is significantly reduced because shifts of the acoustic filter 102 in the passband are reduced. Furthermore, by reducing the drift in the passband due to temperature, the differences in the average and maximum values of ILs are reduced. This is significant from the point of view of a datasheet, since this provides better production yield and a higher capability index (CPK). CPK measures the ability of a process to produce outputs within specified limits while using an estimate of a sigma and incorporating the process of a mean. When CPK equals one, then 99.73% of all data points will fall within the specification limits, indicating that the process is highly capable of meeting its specifications.

Reducing the drift in the passband provides more uniform RF performances for parameters such as available RF power, noise, and transmit efficiency. Finally, reducing the drift in the passband provides better Wi-Fi channel utilization, better coexistence, and easier impedance matching (e.g., impedance matching to an external antenna).

The acoustic filter 102 includes a plurality of acoustic resonators S010, S01+, S01−, S02, S03, S04, P01, P02, P03, P04. The switch device 104 is a double pole/triple throw switch. Accordingly, the switch device 104 has a pole terminal PTT connected to the output of the power amplifier 110 and a pole terminal PTR connected to the input of the low noise amplifier 112. By selectively coupling to the pole terminal PTT or to the pole terminal PTR, the switch device 104 is configured to selectively couple the acoustic filter 102 to either the power amplifier 110 or the low noise amplifier 112.

The acoustic filter 102 has the acoustic resonators S010, S01+, S01−, S02, S03, S04, P01, P02, P03, P04 arranged in a ladder network. The acoustic filter 102 includes an input filter path having the acoustic resonator S010 connected in series between a throw terminal TT0 of the switch device 104 and a node N1. The acoustic filter 102 includes another input filter path having the acoustic resonator S01+ connected in series between a throw terminal TT+ of the switch device 104 and the node N1. The acoustic filter 102 includes another input filter path having the acoustic resonator S01− connected in series between a throw terminal TT− of the switch device 104 and the node N1. The acoustic filter 102 includes a shunt filter path having the acoustic resonator P01 and an inductor L1 connected in series. The shunt filter path having the acoustic resonator P01 and the inductor L1 is connected in shunt to the node N1. The acoustic resonator S02 is a series resonator that is connected between the node N1 and a node N2. The acoustic filter 102 includes a shunt filter path having the acoustic resonator P02 and an inductor L2 connected in series. The shunt filter path having the acoustic resonator P02 and the inductor L2 is connected in shunt to the node N2. The acoustic filter 102 includes a shunt filter path having the acoustic resonator P03 and an inductor L3 connected in series. The acoustic resonator S03 is a series resonator that is connected between the node N2 and a node N3. The shunt filter path having the acoustic resonator P03 and the inductor L3 is connected in shunt to the node N3. The acoustic filter 102 includes a shunt filter path having the acoustic resonator P04 and an inductor L4 connected in series. The acoustic resonator S04 is a series resonator that is connected between the node N3 and a node N4. The node N4 is connected directly to the antennal terminal ANT.

The switch device 104 is configured to selectively couple the upstream/downstream circuitry 106 to the filter path with the acoustic resonator S010, the filter path with the acoustic resonator S01+, and the filter path with the acoustic resonator S01−. For example, the switch device 104 is configured to selectively couple the pole terminal PTT (coupled to the output of the power amplifier 110) to one of either the throw terminal TT0 (coupled to the acoustic resonator S010), the throw terminal TT+(coupled to the acoustic resonator S01+), or the throw terminal TT− (coupled to the acoustic resonator S01−). Additionally, the switch device 104 is configured to selectively couple the pole terminal PTR (coupled to the input of the low noise amplifier 112) to one of either the throw terminal TT0 (coupled to the acoustic resonator S010), the throw terminal TT+(coupled to the acoustic resonator S01+), or the throw terminal TT− (coupled to the acoustic resonator S01−). When the pole terminal PTT and/or the pole terminal PTR is selectively coupled to the throw terminal TT0 while being selectively decoupled from the throw terminals TT−, TT+, the acoustic resonator S010 is configured to provide the passband of the acoustic filter 102 with a particular frequency range. When the pole terminal PTT and/or the pole terminal PTR is selectively coupled to the throw terminal TT+ while being selectively decoupled from the throw terminals TT−, TT0, the acoustic resonator S01+ is configured to provide the passband of the acoustic filter 102 with a frequency range that is higher (at least one higher edge frequency) than the particular frequency range provided when the throw terminal TT0 is selectively coupled. When the pole terminal PTT and/or the pole terminal PTR is selectively coupled to the throw terminal TT− while being selectively decoupled from the throw terminals TT+, TT0, the acoustic resonator S01− is configured to provide the passband of the acoustic filter 102 with a frequency range that is lower (at least one lower edge frequency) than the particular frequency range provided when the terminal TT0 is selectively coupled. In this manner, the switch device 104 is configured to selectively couple either the input path with the acoustic resonator S010, the input path with the acoustic resonator S01+, or the input path with the acoustic resonator S01− to the upstream/downstream circuitry 106 and shift the passband accordingly. It should be noted that by “selectively coupling” one of a filter paths to the upstream/downstream circuitry 106, one of the filter paths is being coupled so as to be operational with an RF signal path that carries input or output RF signals to or from the upstream/downstream circuitry 106. In this example, either the input path with the acoustic resonator S010, the input path with the acoustic resonator S01+, or the input path with the acoustic resonator S01− becomes a part of the RF signal path and, thus, is being selectively coupled to the RF signal path.

The temperature circuitry 108 is configured to measure a measured temperature that is related to a filter temperature of the acoustic filter 102. The temperature circuitry 108 is configured to operate the switch device 104 such that the filter path with the acoustic resonator S010 is selectively coupled to the upstream/downstream circuitry 106 (either the power amplifier 110 or the low noise amplifier 112) in response to the measured temperature being between a first threshold temperature value and a second threshold temperature value. When the measured temperature is between the first threshold temperature value and the second threshold temperature value, the passband of the acoustic filter 102 is considered to be operating within a normal operating frequency range.

When the measured temperature is above the first threshold temperature value, this means that that the rise of the filter temperature has caused a frequency drift downward in the passband of the acoustic filter 102. In order to get the passband back in the normal operating frequency range, the temperature circuitry 108 is configured to selectively couple the filter path with the acoustic resonator S01+ to the upstream/downstream circuitry 106. By selectively coupling the filter path with the acoustic resonator S01+ to the upstream/downstream circuitry 106, the passband of the acoustic filter 102 is shifted upward, returning to the normal operating frequency range.

In contrast, when the measured temperature is below the second threshold temperature value, this means that that the decrease of the filter temperature has caused a frequency drift upward in the passband of the acoustic filter 102. In order to get the passband back in the normal operating frequency range, the temperature circuitry 108 is configured to selectively couple the filter path with the acoustic resonator S01− to the upstream/downstream circuitry 106. By selectively coupling the filter path with the acoustic resonator S01− to the upstream/downstream circuitry 106, the passband of the acoustic filter 102 is shifted downward, returning to the normal operating frequency range.

Note that, while the acoustic filter 102 includes 3 input filter paths (the filter path with the acoustic resonator S010, the filter path with the acoustic resonator S01+, and the filter path with the acoustic resonator S01−), the acoustic filter 102 may include any number of input paths with any number of acoustic resonators. Each of these filter paths can provide a frequency shift associated with a threshold temperature value in order to maintain the passband of the frequency band within the normal operating range.

The temperature circuitry 108 includes a temperature sensor 114 and switch operation circuitry 116. In some embodiments, the temperature sensor 114 may be a thermocouple, a thermistor, a resistance temperature detector, an IC temperature sensor, a micro-electro-mechanical system (MEMs) based temperature sensor, and/or the like. The measured temperature measured by the temperature sensor 114 is to be related to the filter temperature of the acoustic filter 102 by any relationship where a measured change in the measured temperature results in a measured frequency shift in the passband of the acoustic filter 102. In this embodiment, the temperature circuitry 108, the low noise amplifier 112, and the switch device 104 are all formed in the same silicon on insulator (SOI) die. Thus, the temperature sensor 114 is simply placed close enough to the acoustic filter 102 so that the measured temperature is determined based on the filter temperature of the acoustic filter 102. In other embodiments, the measured temperature of the acoustic filter 102 is the filter temperature at some location of the acoustic filter 102. In some embodiments, the particular relationship between the measured temperature and the filter temperature is not important. Instead, all that is required is that the measured temperature have some relationship with the filter temperature so that a change in the measured temperature can be associated with a quantified frequency shift in the passband.

The switch operation circuitry 116 is configured to receive one or more signals from the temperature sensor 114 that indicates the measured temperature in order to operate the switch device 104. In some embodiments, the one or more signals may include one or more voltages that indicate the measured temperature. The switch operation circuitry 116 may include voltage comparators that operate digital logic so as to selectively couple one of the input filter paths based on the measured temperature as described above. The switch operation circuitry 116 may generate one or more control signals to operate the switch device 104 accordingly. In this embodiment, the switch operation circuitry 116 is configured to receive a T/R control that indicates either a transmit mode or a receive mode. In response to the T/R control indicating the transmit mode, the pole terminal PTT is selectively coupled to one of the throw terminals TT0, TT−, TT+ while the pole terminal PTR is selectively decoupled from all of the throw terminals TT0, TT−, TT+. In contrast, in response to the T/R control indicating the receive mode, the pole terminal PTR is selectively coupled to one of the throw terminals TT0, TT−, TT+ while the pole terminal PTT is selectively decoupled from all of the throw terminals TT0, TT−, TT+.

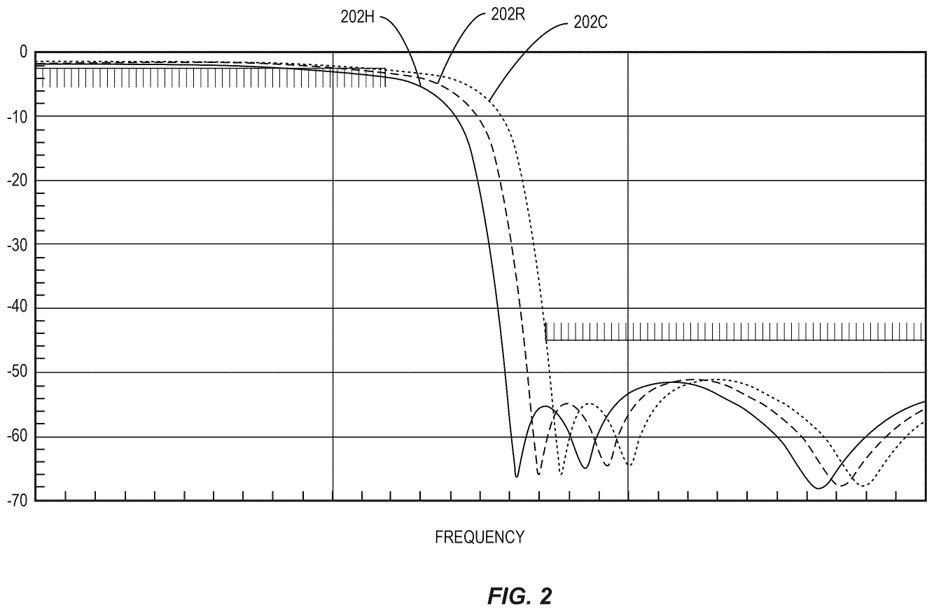

FIG. 2 illustrates an upper band edge of passbands 202C, 202R, 202H, in accordance with some embodiments.

The passband 202R is the passband of the acoustic filter 102 (see FIG. 1) when the passband is at room or nominal temperature ranges. The passband 202C is the passband of the acoustic filter 102 when the passband is in a cold temperature range. The passband 202H is the passband of the acoustic filter 102 when the passband is in a hot temperature range. As shown by FIG. 2, the upper band edge of the passband 202C drifts to higher frequency ranges in comparison to the passband 202R at room or nominal temperature ranges. Additionally, the upper band edge of the passband 202H drifts to lower frequency ranges in comparison to the passband 202R at room or nominal temperature ranges.

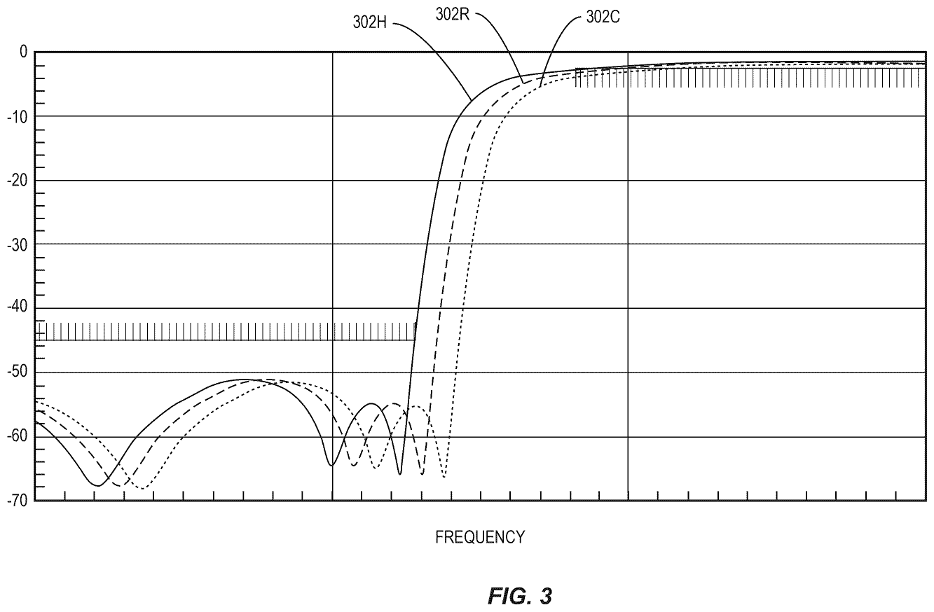

FIG. 3 illustrates a lower band edge of passbands 302C, 302R, 302H, in accordance with some embodiments.

The passband 302R is the passband of the acoustic filter 102 (see FIG. 1) when the passband is at room or nominal temperature ranges. The passband 302C is the passband of the acoustic filter 102 when the passband is in a cold temperature range. The passband 302H is the passband of the acoustic filter 102 when the passband is in a hot temperature range. As shown by FIG. 3, the lower band edge of the passband 302C drifts to higher frequency ranges in comparison to the passband 302R at room or nominal temperature ranges. Additionally, the lower band edge of the passband 302H drifts to lower frequency ranges in comparison to the passband 302R at room or nominal temperature ranges.

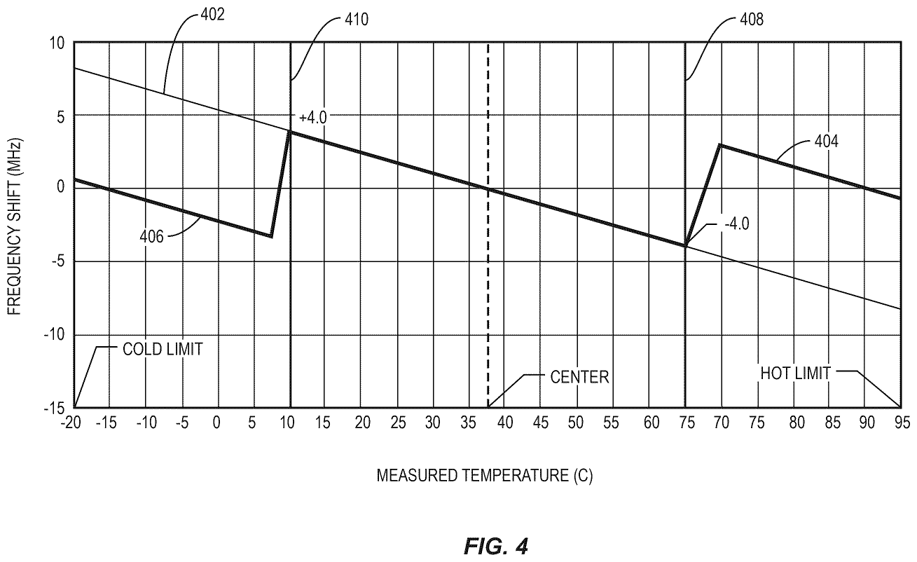

FIG. 4 is a graph that illustrates frequency shift versus measured temperature related to the filter temperature of the acoustic filter 102 shown in FIG. 1, in accordance with some embodiments.

A line 402 illustrates the relationship between the frequency shift and the measured temperature when the filter path with the acoustic resonator S010 is selectively coupled to the upstream/downstream circuitry 106 by the switch device 104 (see FIG. 1). A line 404 illustrates the relationship between the frequency shift and the measured temperature when the filter path with the acoustic resonator S01+ is selectively coupled to the upstream/downstream circuitry 106 by the switch device 104 (see FIG. 1). A line 406 illustrates the relationship between the frequency shift and the measured temperature when the filter path with the acoustic resonator S01− is selectively coupled to the upstream/downstream circuitry 106 by the switch device 104 (see FIG. 1).

In response to the measured temperature being between a first threshold temperature 408 (in this example, 65 degrees Celsius) and a second threshold temperature 410 (in this example, 10 degrees Celsius), the temperature circuitry 108 (see FIG. 1) is configured to operate the switch device 104 such that the filter path with the acoustic resonator S01+ is selectively coupled to the upstream/downstream circuitry 106 by the switch device 104. In this case, the acoustic filter 102 follows the relationship according to the line 402.

In response to the measured temperature being above the first threshold temperature 408 (in this example, 65 degrees Celsius), the temperature circuit 108 is configured to operate the switch device 104 such that the filter path with the acoustic resonator S01+ is selectively coupled to the upstream/downstream circuitry 106 by the switch device 104. In this case, the acoustic filter 102 follows the relationship according to line 404. As shown by the graph, at the first threshold temperature, the frequency shift is equal to −4 MHz. Accordingly, the filter path with the acoustic resonator S01+ is selectively coupled to provide an upward frequency shift and maintain the passband within the normal operating frequency range (with a frequency shift of less than 4 MHz).

In response to the measured temperature being below the second threshold temperature 410 (in this example, 10 degrees Celsius), the temperature circuit 108 is configured to operate the switch device 104 such that the filter path with the acoustic resonator S01− is selectively coupled to the upstream/downstream circuitry 106 by the switch device 104. In this case, the acoustic filter 102 follows the relationship according to line 406. As shown by the graph, at the first threshold temperature, the frequency shift is equal to +4 MHz. Accordingly, the filter path with the acoustic resonator S01− is selectively coupled to provide a downward frequency shift and maintain the passband within the normal operating frequency range.

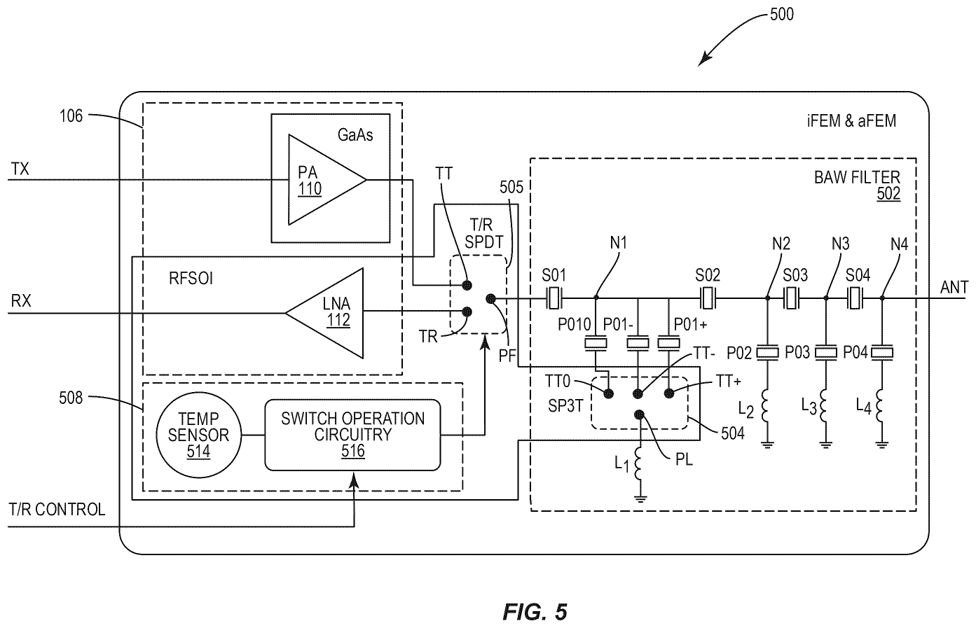

FIG. 5 illustrates an RF circuit 500, in accordance with some embodiments.

In some embodiments, the RF circuit 500 shown in FIG. 5 is a Wi-Fi FEM that is provided in an IC package. Note that the arrangement of the RF circuit 500 is only one arrangement and that other embodiments of the RF circuit 500 may have other arrangements. The RF circuit 500 includes an acoustic filter 502, a switch device 504, a switch device 505, the upstream/downstream circuitry 106 (as described in FIG. 1), and temperature circuitry 508. In FIG. 5, the acoustic filter 502 is a BAW filter. In other embodiments, the acoustic filter 502 may be a SAW filter.

The acoustic filter 502 operates as an RF filter for the upstream/downstream circuitry 106, where the upstream/downstream circuitry 106 is described with respect to FIG. 1. It is important to note that, while the RF circuit 500 in FIG. 5 is shown in a single IC package, other embodiments of the RF circuit 500 may be provided in multiple IC packages since different components of the RF circuit 500 may be included in different IC packages.

In FIG. 5, the switch device 505 is configured to operate as a T/R switch so that the acoustic filter 502 is selectively coupled to either the power amplifier 110 or to the low noise amplifier 112, both of which were originally described in FIG. 1. In this example, the switch device 505 is a single pole, double throw switch. An output of the power amplifier 110 is coupled to a throw terminal TT and an input of the low noise amplifier 112 is coupled to a throw terminal TR. The acoustic filter 502 is connected to the switch device 505 at a pole terminal PF.

The temperature circuit 508 includes a temperature sensor 514 and switch operation circuitry 516. The switch operation circuitry 516 is configured to receive the T/R control signal (i.e., the T/R switch in FIG. 5). The T/R control signal is configured to indicate either a transmit mode or a receive mode. In response to the T/R control signal indicating the transmit mode, the switch operation circuitry 516 is configured to operate the switch device 505 such that the pole terminal PF is selectively coupled to the throw terminal TT and the throw terminal TR is selectively decoupled to the pole terminal PF. In this manner, the power amplifier 110 is selectively coupled to the acoustic filter 502 and the acoustic filter 502 is selectively decoupled to the low noise amplifier 112. In response to the T/R control signal indicating the receive mode, the switch operation circuitry 516 is configured to operate the switch device 505 such that the pole terminal PF is selectively decoupled to the throw terminal TT and the throw terminal T/R is selectively coupled to the pole terminal PF. In this manner, the power amplifier 110 is selectively decoupled to the acoustic filter 502 and the acoustic filter 502 is selectively coupled to the low noise amplifier 112. The switch operation circuit is configured to generate one or more control signals that are configured to operate the switch device 505 accordingly.

The acoustic filter 502 is configured to define a passband that drifts based on a filter temperature of the acoustic filter 502. More specifically, the acoustic filter 502 has a negative temperature coefficient with respect to frequency. This means that, as the filter temperature of the acoustic filter 502 increases, the passband of the acoustic filter 502 shifts down in frequency and, as the filter temperature of the acoustic filter 502 decreases, the passband of the acoustic filter 502 shifts up in frequency. The temperature circuitry 508 is configured to measure a measured temperature that is related to the filter temperature and to operate the switch device 504 such that different components of the acoustic filter 502 are selectively coupled to the upstream/downstream circuitry 106. As explained in further detail below, by selectively coupling different components of the acoustic filter 502 to the upstream/downstream circuitry 106, the drift in the passband of the acoustic filter 502 is reduced.

Reducing the frequency drift due to the filter temperature of the acoustic filter 502 is advantageous. For example, reducing the temperature drift of the acoustic filter 502 lowers insertion losses because the passband of the acoustic filter 502 can be widened. Furthermore, the insertion losses at the edges of the passband are significantly reduced because the acoustic filter 502 shifts in the passband are reduced. Furthermore, by reducing the drift in the passband due to temperature, the differences in the average and maximum values of the ILs are reduced. This is significant from the point of view of a datasheet, since this provides better production yield and higher CPK. Reducing the drift in the passband also provides more uniform RF performances for parameters such as available RF power, noise figure, and transmit efficiency. Finally, reducing the drift in the passband provides better Wi-Fi channel utilization, better coexistence, and makes impedance matching easier (e.g., impedance matching to an external antenna).

The acoustic filter 502 includes a plurality of acoustic resonators S01, S02, S03, S04, P010, P01+, P01−, P02, P03, P04. The switch device 504 is a single pole/triple throw switch. Accordingly, the switch device 504 has a pole terminal PL. The acoustic filter 502 includes an inductor L1. A first end of the inductor L1 is connected to the pole terminal PL and a second end of the inductor L1 is connected to ground.

The acoustic filter 502 has the acoustic resonators S01, S02, S03, S04, P010, P01+, P01−, P02, P03, P04 arranged in a ladder network. The acoustic filter 502 includes an input filter path having the acoustic resonator S01 connected in series between the pole terminal PF and a node N1. A first shunt filter path includes the acoustic resonator P010. The first shunt filter path with the acoustic resonator P010 is coupled in shunt to the node N1. More specifically, a first end of the acoustic resonator P010 is connected to the node N1 and a second end of the acoustic resonator P010 is connected to a throw terminal TT0 of the switch device 504. A second shunt filter path includes the acoustic resonator P01−. The second shunt filter path with the acoustic resonator P01− is coupled in shunt to the node N1. More specifically, a first end of the acoustic resonator P01− is connected to the node N1 and a second end of the acoustic resonator P01− is connected to a throw terminal TT− of the switch device 504. A third shunt filter path includes the acoustic resonator P01+. The third shunt filter path with the acoustic resonator P01+ is coupled in shunt to the node N1. More specifically, a first end of the acoustic resonator P01+ is connected to the node N1 and a second end of the acoustic resonator P01+ is connected to a throw terminal TT+ of the switch device 504.

The acoustic resonator S02 is a series resonator that is connected between the node N1 and a node N2. The acoustic filter 502 includes a shunt filter path having the acoustic resonator P02 and an inductor L2 connected in series. The shunt filter path having the acoustic resonator P02 and the inductor L2 is connected in shunt to the node N2. The acoustic resonator S03 is a series resonator that is connected between the node N2 and a node N3. The acoustic filter 502 includes a shunt filter path having the acoustic resonator P03 and an inductor L3 connected in series. The shunt filter path having the acoustic resonator P03 and the inductor L3 is connected in shunt to the node N3. The acoustic resonator S04 is a series resonator that is connected between the node N3 and a node N4. The node N4 is connected directly to an antenna terminal ANT. The antenna terminal ANT may be coupled to an antenna that is external to the IC package that includes the RF circuit 500.

The switch device 504 is configured to selectively couple the upstream/downstream circuitry 106 to the first shunt filter path with the acoustic resonator P010, the second shunt filter path with the acoustic resonator P01−, and the third shunt filter path of the acoustic resonator P01+. For example, the switch device 504 is configured to selectively couple the pole terminal PL (coupled to the first end of the inductor L1) to one of either the throw terminal TT0 (coupled to the second end of the acoustic resonator P010), the throw terminal TT− (coupled to the second end of the acoustic resonator P01−), or the throw terminal TT+ (coupled to the second end of the acoustic resonator S01+). When the pole terminal PL is selectively coupled to the throw terminal TT0 while being selectively decoupled from the throw terminals TT−, TT+, the acoustic resonator P010 is configured to provide the passband of the acoustic filter 502 within a particular frequency range. When the pole terminal PL is selectively coupled to the throw terminal TT+ while being selectively decoupled from the throw terminals TT−, TT0, the acoustic resonator P01+ is configured to provide the passband of the acoustic filter 502 with a frequency range that is higher (at least one higher edge frequency) than the particular frequency range provided when the throw terminal TT0 is selectively coupled. When the pole terminal PL is selectively coupled to the terminal TT− while being selectively decoupled from the throw terminals TT+, TT0, the acoustic resonator P01− is configured to provide the passband of the acoustic filter 502 with a frequency range that is lower (at least one lower edge frequency) than the particular frequency range provided when the throw terminal TT0 is selectively coupled. In this manner, the switch device 504 is configured to selectively couple either the first shunt path with the acoustic resonator P010, the second shunt filter path with the acoustic resonator P01−, or the third shunt filter path with the acoustic resonator P01+ to the upstream/downstream circuitry 106 and shift the passband accordingly. It should be noted that “selectively coupling” one of the filter paths to the upstream/downstream circuitry 106 means that one of the filter paths is being coupled so as to be operational with an RF signal path that carries input or output RF signals to or from the upstream/downstream circuitry 106. In this example, either the first shunt filter path with the acoustic resonator P010, the second shunt filter path with the acoustic resonator S01−, or the third shunt filter path with the acoustic resonator P01+ is being closed by the switch device 504, thereby allowing the shunt filter path to become operation with the RF signal path that is carrying input or output RF signals from the upstream/downstream circuitry 106.

The temperature circuitry 508 is configured to measure a measured temperature that is related to a filter temperature of the acoustic filter 502. The temperature circuitry 508 is configured to operate the switch device 504 such that the first shunt filter path with the acoustic resonator P010 is selectively coupled to the upstream/downstream circuitry 106 in response to the measured temperature being between the first threshold temperature value and the second threshold temperature value (wherein the first threshold temperature value is higher than the second threshold temperature value). When the measured temperature is between the first threshold temperature value and the second threshold temperature value, the passband of the acoustic filter 502 is considered to be operating within a normal operating frequency range.

When the measured temperature is above the first threshold temperature value, this means that that the rise of the filter temperature has caused a frequency drift downward in the passband of the acoustic filter 502. In order to get the passband back in the normal operating frequency range, the temperature circuitry 508 is configured to selectively couple the third shunt filter path with the acoustic resonator P01+ to the upstream/downstream circuitry 106. By selectively coupling the third shunt filter path with the acoustic resonator S01+ to the upstream/downstream circuitry 106, the passband of the acoustic filter 502 is shifted upward back into the normal operating frequency range.

In contrast, when the measured temperature is below the second threshold temperature value, this means that that the decrease of the filter temperature has caused a frequency drift upward in the passband of the acoustic filter 502. In order to get the passband back in the normal operating frequency range, the temperature circuitry 508 is configured to selectively couple the second shunt filter path with the acoustic resonator P01− to the upstream/downstream circuitry 106. By selectively coupling the filter path with the acoustic resonator P01− to the upstream/downstream circuitry 106, the passband of the acoustic filter 502 is shifted downward back into the normal operating frequency range.

Note that, while the acoustic filter 502 includes 3 shunt filter paths (the shunt filter path with the acoustic resonator P010, the shunt filter path with the acoustic resonator P01+, and the shunt filter path with the acoustic resonator P01−), the acoustic filter 502 may include any number of input paths with any number of acoustic resonators. Each of these filter paths can provide a frequency shift associated with a threshold temperature value in order to maintain the passband of the frequency band within the normal operating range.

The temperature circuitry 508 includes the temperature sensor 514 and the switch operation circuitry 516. In some embodiments, the temperature sensor 514 may be a thermocouple, a thermistor, a resistance temperature detector, an IC temperature sensor, a MEMs based temperature sensor, and/or the like. The measured temperature measured by the temperature sensor 514 is to be related to the filter temperature of the acoustic filter 502 by any relationship where a measured change in the measured temperature results in a measured frequency shift in the passband of the acoustic filter 502. In this embodiment, the temperature circuitry 508, the low noise amplifier 112, the switch device 504, and the switch device 505 are all formed in the same SOI die. Thus, the temperature sensor 514 is simply placed close enough to the acoustic filter 502 so that the measured temperature is determined based on the filter temperature of the acoustic filter 502. In other embodiments, the measured temperature of the acoustic filter 502 is the filter temperature at some location of the acoustic filter 502. In some embodiments, the particular relationship between the measured temperature and the filter temperature is not important. Instead, all that is required is that the measured temperature have some relationship with the filter temperature so that a change in the measured temperature can be associated with a quantified frequency shift in the passband.

The switch operation circuitry 516 is configured to receive one or more signals from the temperature sensor 514 that indicate the measured temperature in order to operate the switch device 504. In some embodiments, the one or more signals may include one or more voltages that indicate the measured temperature. The switch operation circuitry 516 may include voltage comparators that operate digital logic so as to selectively couple one of the input filter paths based on the measured temperature as described above. The switch operation circuitry 516 may generate one or more control signals to operate the switch device 504 accordingly.

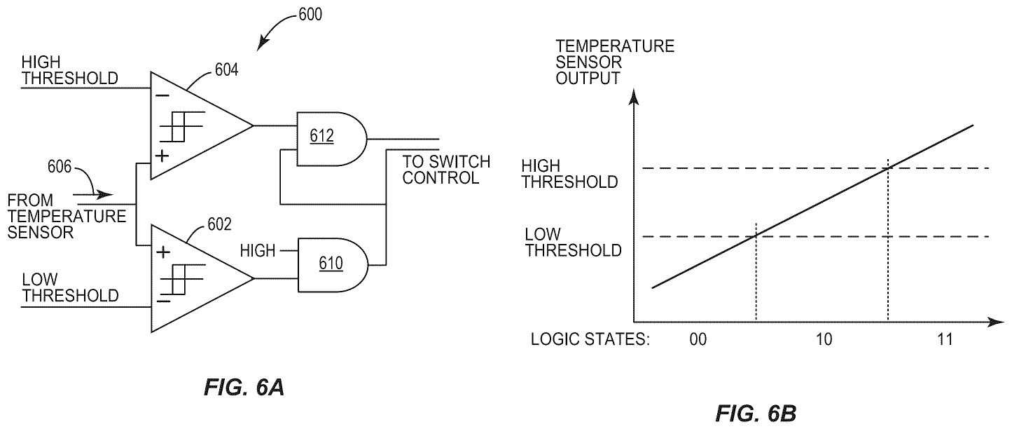

FIG. 6A illustrates switch operation circuitry 600 and FIG. 6B is a graph that illustrates the logical states of the switch operation circuitry versus a temperature sensor output, in accordance with some embodiments.

The switch operation circuitry 600 in FIG. 6B may be the same as or be a part of the switch operation circuitry 116 shown in FIG. 1 or the switch operation circuitry 508 shown in FIG. 5.

The switch operation circuitry 600 includes a voltage comparator 602 and a voltage comparator 604. The voltage comparator 602 has a non-inverting input terminal configured to receive a temperature sensor output 606. The temperature sensor output 606 is generated by the temperature sensor 114 as described in FIG. 1. The temperature sensor output 606 is generated by the temperature sensor 514 as described in FIG. 5. The temperature sensor output 606 is a voltage generated so that a voltage level of the voltage indicates a measured temperature that is related to the filter temperature. In FIG. 6A, the switch operation circuitry 600 performs voltage based operations. In other embodiments, the switch operation circuitry 600 may perform different types of operations (e.g., current based operations) and the temperature sensor output 606 may indicate the measured temperature in a different manner (e.g., a current level of a current).

The voltage comparator 602 has a non-inverting terminal that is configured to receive the temperature sensor output 606 and the voltage comparator 604 has another non-inverting terminal that is configured to receive the temperature sensor output 606. The voltage comparator 604 has an inverting terminal that is configured to receive a voltage at a first reference voltage level while the voltage comparator 602 has an inverting terminal that is configured to receive a voltage at a second reference voltage level. The first reference voltage level (i.e., high threshold) is higher than the second reference voltage level (i.e., low threshold) so that the first reference voltage level corresponds to a first threshold temperature value and the second reference voltage level corresponds to a second threshold temperature value. The first threshold temperature value is higher than the second threshold temperature value.

The switch operation circuitry 600 includes an AND gate 610 and an AND gate 612. The AND gate 610 has a first input terminal connected to an output of the voltage comparator 602 and a second input terminal connected to receive a voltage in a high voltage state (i.e., HIGH in FIG. 6). The AND gate 612 has a first input terminal that is configured to receive an output of the voltage comparator 604 and a second input terminal that is configured to receive the output of the AND gate 610.

FIG. 6B illustrates logical states in the X-axis where the first logical state is the output of the AND gate 610 and the second logical state is the output of the AND gate 612. As shown in FIG. 6B, in response to the temperature sensor output 606 being below both the first reference voltage level (i.e., the high threshold) and the second reference voltage level (i.e., the low threshold), the output of the AND gate 610 is “0” and the output of the AND gate 612 is “0.” This indicates that the measured temperature is below both the first threshold temperature value and the second threshold temperature value. With respect to FIG. 1, in response to the measured temperature being below both the first threshold temperature value and the second threshold temperature value, the temperature circuitry 108 is configured to operate the switch device 104 to selectively couple the upstream/downstream circuit 106 to the filter path with the acoustic resonator S01−. With respect to FIG. 5, in response to the measured temperature being below both the first threshold temperature value and the second threshold temperature value, the temperature circuitry 508 is configured to operate the switch device 504 to selectively couple the upstream/downstream circuit 106 to the shunt filter path with the acoustic resonator P01−.

As shown in FIG. 6B, in response to the temperature sensor output 606 being below the first reference voltage level (i.e., the high threshold) but above the second reference voltage level (i.e., the low threshold), the output of the AND gate 610 is “1” and the output of the AND gate 612 is “0.” This indicates that the measured temperature is below the first threshold temperature value but above the second threshold temperature value. With respect to FIG. 1, in response to the measured temperature being below the first threshold temperature value but above the second threshold temperature value, the temperature circuitry 108 is configured to operate the switch device 104 to selectively couple the upstream/downstream circuit 106 to the filter path with the acoustic resonator S010. With respect to FIG. 5, in response to the measured temperature being below the first threshold temperature value but above the second threshold temperature value, the temperature circuitry 508 is configured to operate the switch device 504 to selectively couple the upstream/downstream circuit 106 to the shunt filter path with the acoustic resonator P010.

As shown in FIG. 6B, in response to the temperature sensor output 606 being above both the first reference voltage level (i.e., the high threshold) and the second reference voltage level (i.e., the low threshold), the output of the AND gate 610 is “1” and the output of the AND gate 612 is “1.” This indicates that the measured temperature is above both the first threshold temperature value and the second threshold temperature value. With respect to FIG. 1, in response to the measured temperature being above both the first threshold temperature value and the second threshold temperature value, the temperature circuitry 108 is configured to operate the switch device 104 to selectively couple the upstream/downstream circuitry 106 to the filter path with the acoustic resonator S01+. With respect to FIG. 5, in response to the measured temperature being above both the first threshold temperature value and the second threshold temperature value, the temperature circuitry 508 is configured to operate the switch device 504 to selectively couple the upstream/downstream circuitry 106 to the shunt filter path with the acoustic resonator P01+.

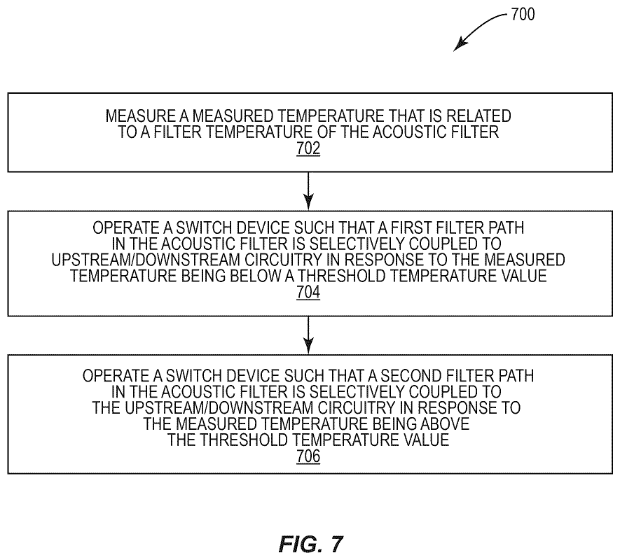

FIG. 7 is a flow diagram 700 of a method of operating an RF circuit, in accordance with some embodiments.

In some embodiments, the RF circuit is the RF circuit 100 in FIG. 1 or the RF circuit 500 in FIG. 5. In some embodiments, the flow diagram 700 is performed by the temperature circuitry 108 in FIG. 1 or the temperature circuitry 508 in FIG. 5. The flow diagram includes blocks 702-706. Flow begins at the block 702.

At the block 702, a measured temperature that is related to the filter temperature of the acoustic filter is measured. In some embodiments, the block 702 is performed by the temperature sensor 114 in FIG. 1. In some embodiments, the block 702 is performed by the temperature sensor 514 in FIG. 5. In some embodiments, the acoustic filter is the acoustic filter 102 in FIG. 1. In some embodiments, the acoustic filter is the acoustic filter 502 in FIG. 5. Flow proceeds to the block 704.

At the block 704, a switch device is operated such that a first filter path in the acoustic filter is selectively coupled to the upstream/downstream circuitry in response to the measured temperature being below a threshold temperature value. In some embodiments, the block 704 is performed by the switch operation circuitry 116 in FIG. 1. In some embodiments, the block 704 is performed by the switch operation circuitry 516 in FIG. 5. In some embodiments, the block 704 is performed by the switch operation circuitry 600 in FIG. 6A.

In some embodiments, the threshold temperature value is the first threshold temperature value discussed with respect to FIG. 1 and FIG. 5. In some embodiments, the threshold temperature value corresponds to the first reference voltage level (i.e., the high threshold) in FIG. 6B. In some embodiments, the first filter path corresponds to the input filter path with the acoustic resonator S010 in FIG. 1. In some embodiments, the first filter path corresponds to the shunt filter path with the acoustic resonator P010 in FIG. 5.

In some embodiments, the threshold temperature value is the second threshold temperature value discussed with respect to FIG. 1 and FIG. 5. In some embodiments, the threshold temperature value corresponds to the second reference voltage level (i.e., the low threshold) in FIG. 6B. In some embodiments, the first filter path corresponds to the input filter path with the acoustic resonator S01− in FIG. 1. In some embodiments, the first filter path corresponds to the shunt filter path with the acoustic resonator P01− in FIG. 5. Flow then proceeds to the block 706.

At the block 706, a switch device is operated such that a second filter path in the acoustic filter is selectively coupled to the upstream/downstream circuitry in response to the measured temperature being above a threshold temperature value. In some embodiments, the block 706 is performed by the switch operation circuitry 116 in FIG. 1. In some embodiments, the block 706 is performed by the switch operation circuitry 516 in FIG. 5. In some embodiments, the block 706 is performed by the switch operation circuitry 600 in FIG. 6A.

In some embodiments, the threshold temperature value is the first threshold temperature value discussed with respect to FIG. 1 and FIG. 5. In some embodiments, the threshold temperature value corresponds to the first reference voltage level (i.e., the high threshold) in FIG. 6B. In some embodiments, the second filter path corresponds to the input filter path with the acoustic resonator S01+ in FIG. 1. In some embodiments, the second filter path corresponds to the shunt filter path with the acoustic resonator P01+ in FIG. 5.

In some embodiments, the threshold temperature value is the second threshold temperature value discussed with respect to FIG. 1 and FIG. 5. In some embodiments, the threshold temperature value corresponds to the second reference voltage level (i.e., the low threshold) in FIG. 6B. In some embodiments, the second filter path corresponds to the input filter path with the acoustic resonator S010 in FIG. 1. In some embodiments, the second filter path corresponds to the shunt filter path with the acoustic resonator P010 in FIG. 5.

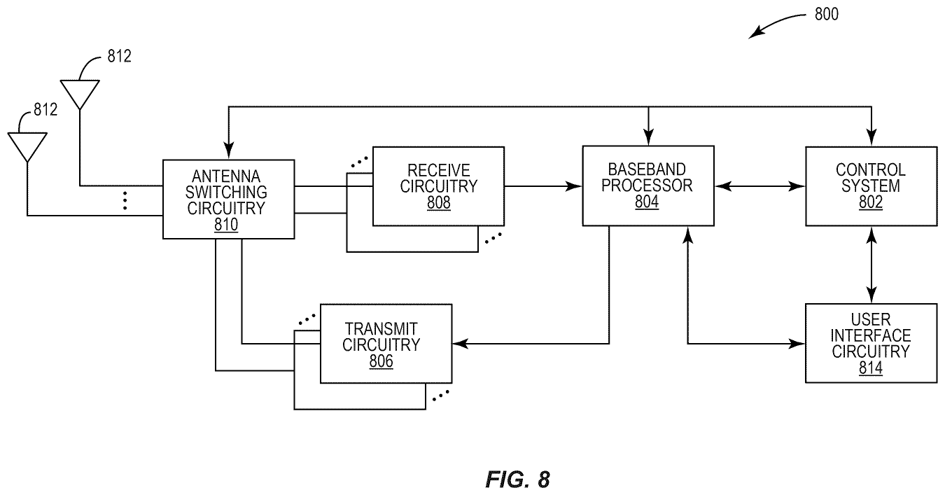

FIG. 8 is a user element 800, in accordance with some embodiments.

With reference to FIG. 8, the concepts described above may be implemented in various types of user elements 800, such as mobile terminals, smart watches, tablets, computers, navigation devices, access points, and like wireless communication devices that support wireless communications, such as cellular, wireless local area network (WLAN), Bluetooth, and near field communications. The user element 800 will generally include a control system 802, a baseband processor 804, transmit circuitry 806, receive circuitry 808, antenna switching circuitry 810, multiple antennas 812, and user interface circuitry 814. In a non-limiting example, the control system 802 may be a field-programmable gate array (FPGA) or an application-specific integrated circuit (ASIC). In this regard, the control system 802 may include at least a microprocessor(s), an embedded memory circuit(s), and a communication bus interface(s). The receive circuitry 808 receives radio frequency signals via the antennas 812 and through the antenna switching circuitry 810 from one or more base stations. A low noise amplifier (e.g., the low noise amplifier 112 in FIG. 1 and FIG. 5) and a filter (the acoustic filter 102 in FIG. 1 or the acoustic filter 502 in FIG. 5) cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC(s)).

The baseband processor 804 processes the digitized received signal to extract the information or data bits conveyed in the received signal. This processing typically comprises demodulation, decoding, and error correction operations, as will be discussed on greater detail below. The baseband processor 804 is generally implemented in one or more digital signal processors (DSPs) and application specific integrated circuits (ASICs).

For transmission, the baseband processor 804 receives digitized data, which may represent voice, data, or control information, from the control system 802, which it encodes for transmission. The encoded data is output to the transmit circuitry 806, where a digital-to-analog converter(s) (DAC(s)) converts the digitally encoded data into an analog signal and a modulator modulates the analog signal onto a carrier signal that is at a desired transmit frequency or frequencies. A power amplifier (e.g., the power amplifier 110 in FIG. 1 and FIG. 5) along with a filter (the acoustic filter 102 in FIG. 1 or the acoustic filter 502 in FIG. 5) cooperate to amplify the modulated carrier signal to a level appropriate for transmission and deliver the modulated carrier signal to the antennas 812 through the antenna switching circuitry 810. The multiple antennas 812 and the replicated transmit and receive circuitries 806, 808 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the embodiments that follow.

What is claimed is:

1. A radio frequency (RF) circuit, comprising:
an acoustic filter comprising a first filter path that includes a first acoustic resonator and a second filter path that includes a second acoustic resonator;
upstream/downstream RF circuitry;
a switch device configured to selectively couple the upstream/downstream RF circuitry to the first filter path and to the second filter path; and
temperature circuitry configured to measure a measured temperature that is related to a filter temperature of the acoustic filter, the temperature circuitry is configured to operate the switch device such that the first filter path is selectively coupled in response to the measured temperature being below a threshold temperature value and such that the second filter path is selected in response to the measured temperature being above the threshold temperature value.

2. The RF circuit of claim 1, wherein:
the threshold temperature value is a first threshold temperature;
the acoustic filter further comprises a third filter path that includes a third acoustic filter;
the switch device is further configured to selectively couple the upstream/downstream RF circuitry to the third filter path; and
the temperature circuitry is configured to operate the switch device so as to selectively couple the upstream/downstream RF circuitry to the second filter path in response to the measured temperature being below a second threshold temperature and so as to selectively couple the upstream/downstream RF circuitry to the third filter path in response to the measured temperature being above the second threshold temperature, wherein the second threshold temperature is higher than the first threshold temperature.

3. The RF circuit of claim 1, wherein the acoustic filter defines a passband and wherein the passband is shifted to higher frequencies in response to the first filter path being selectively coupled to the upstream/downstream RF circuitry and the passband is shifted to lower frequencies in response to the second filter path being selectively coupled to the upstream/downstream RF circuitry.

4. The RF circuit of claim 1, wherein:
the acoustic filter comprises a plurality of acoustic resonators including the first acoustic resonator and the second acoustic resonator;
the first filter path is a first input filter path of the acoustic filter; and
the second filter path is a second input filter path of the acoustic filter, wherein the first input filter path and the second input filter path are connected in parallel such that the upstream/downstream RF circuitry is selectively coupled by the switch device to the acoustic filter through the first input filter path or through the second input filter path.

5. The RF circuit of claim 4, wherein the acoustic filter is a bulk acoustic wave (BAW) filter.

6. The RF circuit of claim 5, wherein the first acoustic resonator is a first BAW resonator and the second acoustic resonator is a second BAW resonator.

7. The RF circuit of claim 1, wherein:
the acoustic filter comprises a plurality of acoustic resonators including the first acoustic resonator and the second acoustic resonator;
the first filter path is a first shunt filter path of the acoustic filter; and
the second filter path is a second shunt filter path of the acoustic filter, wherein the first shunt filter path and the second shunt filter path are selectively coupled in shunt to an RF signal line in the acoustic filter by the switch device.

8. The RF circuit of claim 7, wherein the acoustic filter is a bulk acoustic wave (BAW) filter.

9. The RF circuit of claim 8, wherein the first acoustic resonator is a first BAW resonator and the second acoustic resonator is a second BAW resonator.

10. The RF circuit of claim 1, wherein the upstream/downstream RF circuitry comprises a power amplifier (PA).

11. The RF circuit of claim 1, wherein the upstream/downstream RF circuitry comprises a low noise amplifier (LNA).

12. A method of operating a radio frequency (RF) circuit, comprising:
measuring a measured temperature that is related to a filter temperature of an acoustic filter;
operating a switch device such that a first filter path in the acoustic filter is selectively coupled to upstream/downstream circuitry in response to the measured temperature being below a threshold temperature value; and
operating the switch device such that a second filter path in the acoustic filter is selectively coupled to the upstream/downstream circuitry in response to the measured temperature being above the threshold temperature value.

13. A user element comprising a radio frequency (RF) circuit, the RF circuit comprising:
an acoustic filter comprising a first filter path that includes a first acoustic resonator and a second filter path that includes a second acoustic resonator;
upstream/downstream RF circuitry;
a switch device configured to selectively couple the upstream/downstream RF circuitry to the first filter path and to the second filter path; and
temperature circuitry configured to measure a measured temperature that is related to a filter temperature of the acoustic filter, the temperature circuitry is configured to operate the switch device such that the first filter path is selectively coupled in response to the measured temperature being below a threshold temperature value and such that the second filter path is selected in response to the measured temperature being above the threshold temperature value.

14. The user element of claim 13, wherein:
the threshold temperature value is a first threshold temperature;
the acoustic filter further comprises a third filter path that includes a third acoustic filter;
the switch device is further configured to selectively couple the upstream/downstream RF circuitry to the third filter path; and
the temperature circuitry is configured to operate the switch device so as to selectively couple the upstream/downstream RF circuitry to the second filter path in response to the measured temperature being below a second threshold temperature and so as to selectively couple the upstream/downstream RF circuitry to the third filter path in response to the measured temperature being above the second threshold temperature, wherein the second threshold temperature is higher than the first threshold temperature.

15. The user element of claim 13, wherein the acoustic filter defines a passband and wherein the passband is shifted to higher frequencies in response to the first filter path being selectively coupled to the upstream/downstream RF circuitry and the passband is shifted to lower frequencies in response to the second filter path being selectively coupled to the upstream/downstream RF circuitry.

16. The user element of claim 13, wherein:
the acoustic filter comprises a plurality of acoustic resonators including the first acoustic resonator and the second acoustic resonator;
the first filter path is a first input filter path of the acoustic filter; and
the second filter path is a second input filter path of the acoustic filter, wherein the first input filter path and the second input filter path are connected in parallel such that the upstream/downstream RF circuitry is selectively coupled by the switch device to the acoustic filter through the first input filter path or through the second input filter path.

17. The user element of claim 13, wherein:
the acoustic filter comprises a plurality of acoustic resonators including the first acoustic resonator and the second acoustic resonator;
the first filter path is a first shunt filter path of the acoustic filter; and
the second filter path is a second shunt filter path of the acoustic filter, wherein the first shunt filter path and the second shunt filter path are selectively coupled in shunt to an RF signal line in the acoustic filter by the switch device.

18. The user element of claim 13, wherein the acoustic filter is a bulk acoustic wave (BAW) filter.

19. The user element of claim 13, wherein the upstream/downstream RF circuitry comprises a power amplifier (PA).

20. The user element of claim 13, wherein the upstream/downstream RF circuitry comprises a low noise amplifier (LNA).
